(19) United States
(12) Patent Application Publication
(10) Pub. No.: US 2004/0129221 A1
(43) Pub. Date: Jul. 8, 2004

(54) Cooled deposition baffle in high density plasma semiconductor processing

(76) Inventors: Jozef Brcka, Mesa, AZ (US); Mark Kleshock, Phoenix, AZ (US); Tim Provencher, Gilbert, AZ (US)

Correspondence Address: WOOD, HERRON & EVANS, LLP, 2700 CAREW TOWER, 441 VINE STREET, CINCINNATI, OH, 45202, US

(21) Appl. No.: 10/338,771

(22) Filed: Jan. 8, 2003

(51) Int. Cl. C23C 16/00

(52) U.S. Cl. 118/723 I; 118/723 AN

(57) ABSTRACT

An improved deposition baffle, that is provided to protect a dielectric window from conductive deposits, is provided in high-density-plasma apparatus. The baffle has a central circular part having slots cut therein that are interrupted by electrically conductive bridges. Ribs in the body between the slots have cooling fluid channel sections bored therein, which are joined in series by interconnecting channel portions in a peripheral annular part of the baffle to form a continuous serpentine cooling fluid flow path from an inlet to an outlet in the annular peripheral part of the baffle.

This invention is related to U.S. Pat. Nos. 6,080,287; 6,197,165 and 6,287,435 and to pending U.S. patent application Ser. No. 09/629,515, filed Aug. 1, 2000, U.S. patent application Ser. No. 09/796,971, filed Mar. 1, 2001 and U.S. patent application Ser. No. 10/080,496, filed Feb. 22, 2002, all hereby expressly incorporated by reference herein.

### FIELD OF THE INVENTION

This invention relates to deposition baffles used in plasma processing machines, and particularly to machines that employ high-density plasmas, for example inductively-coupled plasmas (ICPs), to process and prepare coatings, especially electrically conductive coatings, in the manufacture of semiconductor devices and integrated circuits. Such deposition baffles protect dielectric walls and windows of a vacuum processing chamber through which RF energy is coupled into the high-density plasma from being coated with the material being deposited.

### BACKGROUND OF THE INVENTION

Inductively coupled plasma (ICP) sources are widely used for processing in the semiconductor manufacturing industry. Typical ICP sources consist of an antenna that provides RF energy for coupling into a working gas within a processing chamber to excite and maintain a plasma. In many such processing applications, the antenna is located outside of an insulating window in the wall of a vacuum chamber and between the antenna and the processing space within the chamber. The window provides an air-to-vacuum barrier while being transparent to the RF energy from the antenna. Planar ICP sources are finding increased utility and provide an antenna and window in an end of a processing chamber.

Ionized physical vapor deposition (iPVD) systems are often used for deposition of metal in semiconductor processing. In such metal as well as many non-metal deposition systems, a deposition baffle is used to protect the dielectric window from coating, particularly by electrically conductive materials. For this purpose, the deposition baffle is placed between the plasma and the window to intercept coating material propagating from the plasma that would otherwise deposit on the window.

High density ICPs often produce significant heat flux onto exposed surfaces in the chamber, including to the deposition baffle. With RF power levels of 5 kilowatt (kW), for example, electron densities of 10¹²cm⁻³ may be achieved. Furthermore, with iPVD sources, DC power on a metal target may add up to 20 kW to the system by sputtering material into the high density plasma. The heat of the baffle and other components produces thermal stresses on the components and on coatings that build up on the components. The thermal stresses cause flaking of the coatings and particle generation that adds contamination to the process and damages devices being formed on the semiconductor substrates.

Particles are also generated in ICP PVD systems as a result of arcing that occurs at low local voltage differences of less than 20-30 volts. Slotted deposition baffles through which the strong RF fields are coupled are susceptible to such arcing, particularly with plasma contraction that occurs due to the geometries of the electrically conductive material of the baffle around the slots. Under such conditions, arcing appears more prevalent and temperature rises of 100° C. are seen.

Accordingly, needs exist to manage temperatures that occur in deposition baffles during plasma processing and to reduce causes of particle generation.

### SUMMARY OF THE INVENTION

An objective of the present invention is to reduce particle generation in semiconductor wafer vacuum processing. A particular objective of the invention is to minimize flaking from deposition baffles in the use of ICP or PVD processing equipment.

A further objective of the present invention is to more effectively cool a deposition baffle in ICP or PVD processing, to minimize the maximum temperature rise on such baffles during processing, and to minimize thermal stresses in such baffles during processing.

According to principles of the present invention, a deposition baffle is cooled relatively uniformly across its extent, and more particularly, is provided with full face cooling features. The maximum temperature of the baffle is maintained, for example, at less than 100° C., and typically below about 40° C., preferably at approximately 30° C.

According to the described embodiments of the invention, a deposition baffle is provided which protects a dielectric window from deposits while facilitating inductive coupling of RF energy from a coil outside of the window. The baffle has an electrically conductive body with a plurality of slots extending therethrough. The slots are configured to interrupt current paths in the body so that, when the baffle is situated in a predetermined position and orientation in relation to an RF antenna, RF energy couples through the baffle. The baffle surface is generally textured or otherwise conditioned to facilitate the adhesion of deposition material to reduce flaking of the material. The slots are preferably configured so that line-of-sight paths for particles in the chamber moving toward the window are blocked. In such a baffle, the rib portions between each pair of adjacent slots contain a section of a cooling fluid channel.

In one embodiment, the baffle body has a cooling fluid inlet and a cooling fluid outlet on opposite sides of an annular border portion. At least one cooling fluid channel forms a cooling fluid path from the inlet to the outlet through a central portion of the baffle that contains the slots, extending along rib portions between the slots, preferably in a single serpentine path from inlet to outlet. The configuration of the channel and the control of the cooling fluid flow therethrough maintains a sufficiently uniform temperature deposition to prevent substantial flaking of deposited material from the conditioned surface of the body and to avoid conditions favorable to arcing.

The body of the baffle is generally flat with the rib portions lying parallel to a plane. The slots in the baffle are typically parallel. The body may include a plurality of electrically conductive bridges, each interrupting a slot so that the slot does not extend across the diameter of the body. The bridges are preferably confined to only the window side of the baffle to further reduce particulates.

The sections of the channel that extend between the slots are preferably connected in series between the inlet and the outlet, interconnected by channel sections in the periphery of the baffle body. The sections thus may form a single continuous serpentine cooling fluid path from the inlet sequentially along each of the intermediate sections of the channel and to the outlet. An inductively-coupled-plasma source using such a baffle is provided.

According to certain embodiments, a baffle body is formed of a central circular part that has slots and ribs formed therein with intermediate channel sections bored along from the periphery of the central part along each of the ribs. The body also has an annular outer part surrounding the central circular part with interconnecting channel portions milled therein to interconnect the intermediate channel sections in series when the annular part is bonded to the rim of the circular part to form the body and enclose the channels.

The present invention provides for a reduction in the maximum temperature of a deposition baffle during the plasma processing of semiconductor wafers, and provides uniform thermal flux in the baffle. Thermal gradients and thus thermal stresses are reduced in the deposition baffle and in deposits that form on the surface of the deposition baffle, as for example, in metal deposits that form in a typical iPVD process. This results in a reduction of particle generation and a suppression of thermionic arching within the baffle.

In particular, the features of the present invention provide significantly more uniform temperature over the entire deposition baffle. Maximum temperature is reduced, for example, to below 100° C. Thermal stress is reduced in individual ribs, bridges, blades and other portions of the deposition baffle. Thermal stresses in the deposits that form on the baffles are also reduced. As a result, flaking of deposits from the baffles is thereby reduced. Particle generation is thereby lower. Conditions are made less favorable for arc generation, thereby reducing contaminates that it would cause. The deposition baffles last longer and need be changed less frequently. Overall process yield and performance is increased.

These and other objectives and advantages of the present invention will be more readily apparent from the following detailed description, in which:

### BRIEF DESCRIPTION OF THE DRAWINGS

FIG. 1 is a cut-away perspective view of an iPVD apparatus, illustrating components of the prior art.

FIG. 2A is a cross-sectional view through the deposition baffle of the iPVD apparatus of FIG. 1 taken at line 2A-2A;

FIG. 2B is a perspective diagram of the cooling fluid passage within the deposition baffle of FIG. 2A.

FIG. 3A is a cross-sectional view, similar to FIG. 2A, through a deposition baffle according to one embodiment of the present invention.

FIG. 3B is a cross-sectional view through the deposition baffle of FIG. 3A taken at line 3A-3A.

FIG. 3C is a diagram, similar to FIG. 2B, of the cooling fluid passage within the deposition baffle of FIGS. 3A and 3B.

FIG. 4A is a graph comparing cooling fluid temperatures for the deposition baffles of FIGS. 2A-2B and FIGS. 3A-3C.

FIG. 4B is a graph comparing cooling fluid temperatures for various cooling fluid flow rates for the deposition baffles of FIGS. 3A-3C.

FIG. 5A is a window side view of an alternative embodiment of the deposition baffle of FIGS. 2A-2B.

FIG. 5B is a cross-sectional view of the deposition baffle of FIG. 5A taken along the line 5B-5B.

### DETAILED DESCRIPTION OF THE DRAWINGS

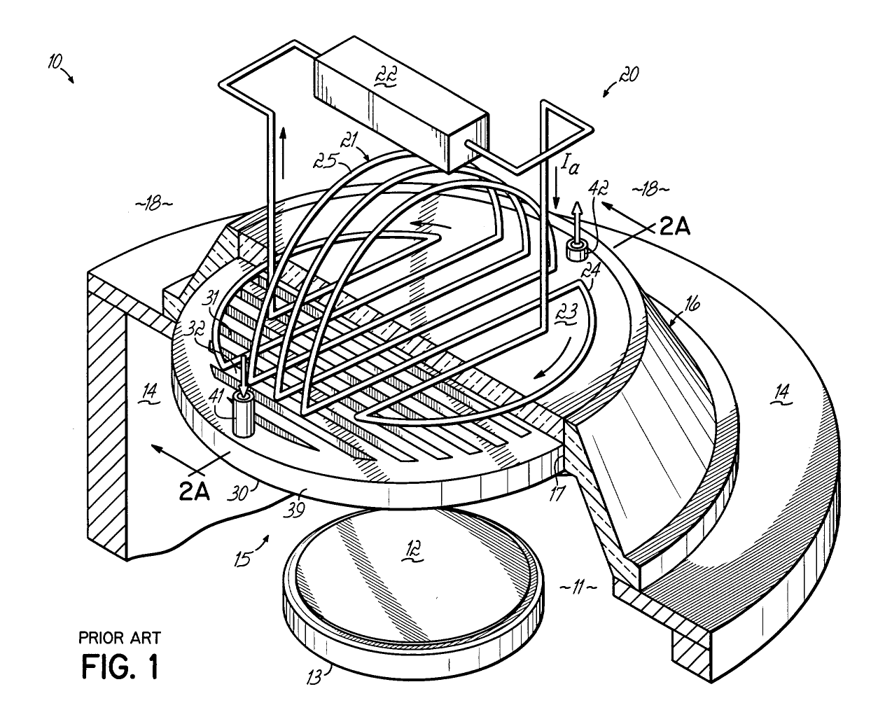

The invention is described in the context of an iPVD apparatus 10 of the type disclosed in U.S. Pat. No. 6,287,435, as diagrammatically illustrated in FIG. 1. The apparatus 10 includes a vacuum chamber 11 bounded by a chamber wall 14 and having a semiconductor wafer 12 supported for processing therein on an upwardly facing substrate support 13. An ionized sputter material source 15 is situated in the top of the chamber 11 and includes a frusto-conical magnetron sputtering target 16 with an RF energy source 20 situated in an opening 17 in the center of the target 16. The source 20 includes an RF coil or antenna 21 connected to the output of an RF power supply and matching network 22. The coil 21 is located in atmosphere 18 outside of the chamber 11, behind a dielectric window 23 that forms a part of the wall 14 of the chamber 11, which isolates a processing gas maintained at a vacuum inside of the chamber 11 from the atmosphere outside of the chamber 11.

Inside of the window 23 is a deposition baffle 30 of electrically conductive material having, in the embodiment shown, a plurality of parallel linear slots 31 therethrough. Typically, the baffle 30 is made of solid metal or of metal clad body 39. The body 39 of the baffle 30 includes, between each pair of adjacent slots 31, an elongated slat or rib 32. The coil 21 has a plurality of parallel conductor segments 24 that lie close to the outside of the window 23 and interconnected by return segments 25 configured so that the currents Iₐ in the segments 24 flow in the same direction and typically perpendicular to the slots 31 of the baffle 30. A cooling fluid channel (not shown in FIG. 1) lies within the baffle body 39 and communicates with a cooling fluid inlet 41 and cooling fluid outlet 42 to provide one or more cooling fluid paths between the inlet 41 and outlet 42.

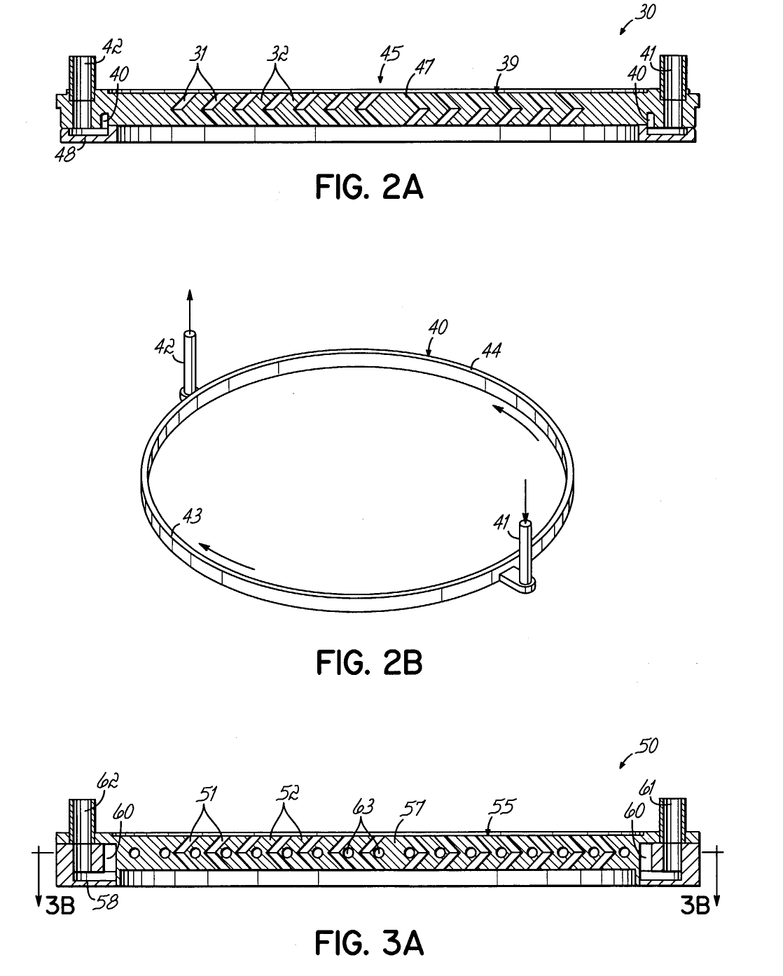

FIGS. 2A and 2B illustrate a deposition baffle 30 of the prior art, in which a cooling fluid channel 40 is provided in two semicircular sections 43 and 44, each of which forms a cooling water path from the inlet 41 to the outlet 42. These two sections 43 and 44 of the channel 40 surround a central portion 45 of the body 39, in which are formed the slots 31 of chevron-shaped cross-section, of which one of the ribs 32 extends between each adjacent pair. This baffle 30 provides heat removal around the rim and relies on the thermal conductivity of the ribs 32 to conduct heat from the center of the baffle 30 to be removed to the outlet 42 by the cooling fluid flowing in the channel sections 43 and 44.

The body 39 of the baffle 30 is manufactured in two parts, including a main body part 47 in which the slots 31 are machined and a cooling channel cap 48, which covers the peripheral rim of the main body part 47 to close the channel sections 43 and 44 that are machined into the rim of the main body part 47. The main body part 47 and cap 48 of the body 39 are typically made of a material such as 6061 Aluminum. The parts 47 and 48 are bonded and sealed together, such as by brazing. The process may, for example, involve fixturing the pieces in a press with a brazing compound in between that promotes adhesion of the two pieces once heat is applied at a temperature that allows the alloys to begin melting, which causes the pieces to bond when pressure is applied. Then the body 39 is cooled to room temperature. Because dimensions are difficult to control in this process, machining is carried out after the bonding is complete. Then the body 39 is coated and conditioned to provide a surface to which deposited coating material will adhere, thereby resisting flaking that will cause particulate contaminates in the iPVD process. Then the surface is cleaned.

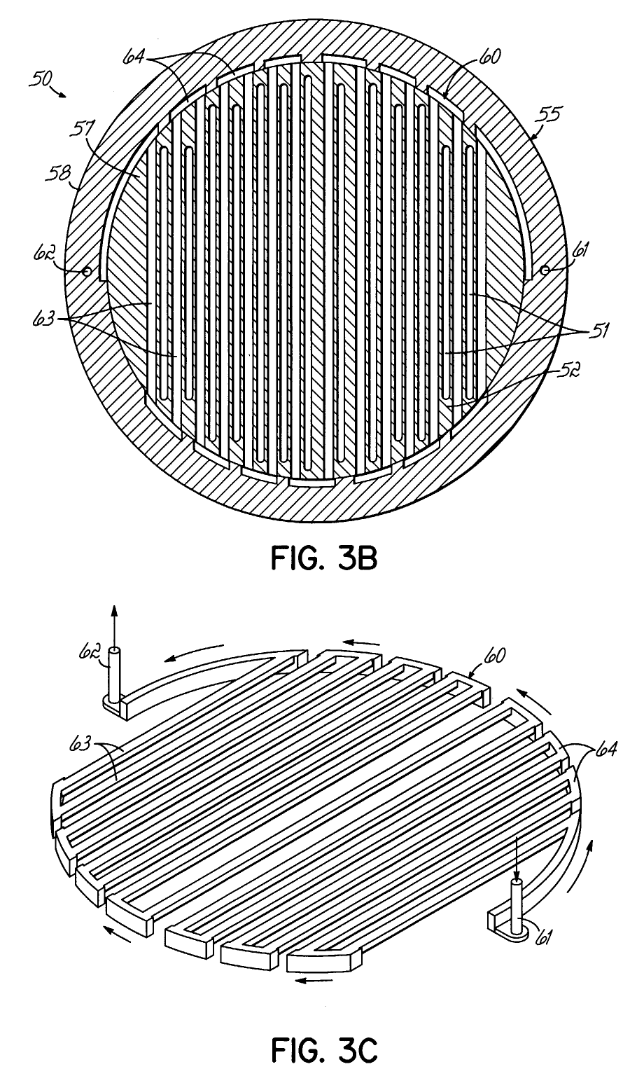

FIGS. 3A-3C illustrate a deposition baffle 50 according to principles of the present invention to be used in place of the baffle 30 of FIG. 1. The baffle 50 may have slots 51 generally configured like the slots 31 of baffle 30 or of some other slot pattern deemed appropriate to block particles from striking the window 23 while facilitating coupling of RF energy from the coil 21. The baffle 50 has a metal or otherwise electrically conductive body 55 having a cooling channel 60 within it that extends in one or more paths between a cooling fluid inlet 61 and a cooling fluid outlet 62. The channel 60 may include more than one parallel fluid path, but in the illustrated embodiment includes a single continuous path from the inlet 61 to the outlet 62.

The channel 60 includes a plurality of intermediate sections 63 that extend the length of each respective one of the ribs 52 and a plurality of interconnecting channel portions 64 that connect adjacent intermediate ones of the sections 63 in series. As such, the channel 60 is in the shape of a single serpentine cooling fluid path through which cooling fluid flows in alternating directions through channel sections in each of the ribs. This provides full-face cooling across the extent of the deposition baffle 50.

The body 55 of the baffle 50 is formed of two parts, including a circular central main body part 57 and an annular outer water jacket cap 58. For iPVD processes for copper and tantalum, the parts may be made from 2024 Aluminum. The main body part 57 has the slots 51 machined therein and includes the ribs 52. The ribs 52 are generally linear and extend across the main body part 57, terminating at each end on the circular perimeter of the main body part 57. The intermediate channel sections 63 extend the entire length of each of the ribs 52, also terminating in the periphery of the main body part 57. The annular outer water jacket cap 58 has an interior surface that is bonded to the perimeter of the main body part 57. In this interior surface are machined interconnecting channel sections 64 that connect adjacent ones of the intermediate channel sections 63 to form a continuous serpentine cooling fluid path formed of the sections 63 and 64 connected in series.

Alignment of the channel sections 63 and 64 is somewhat more critical than the simple brazing method, described in connection with the baffle 30 above, provides. The parts 63 and 64 are completely machined before being bonded together. After machining, the parts 63 and 64 are joined by electron beam welding, which allows controlled penetration of the alloys, melting them together and providing a water and vacuum tight connection between them. Material distortion of the parts 63 and 64 during bonding is minimized due to the localized heat produced by the electron beam welding process. After bonding, the body 55 is coated and conditioned to provide a surface to which deposited coating material will adhere, thereby resisting flaking that will cause particulate contaminates in the iPVD process. Then the surface is cleaned.

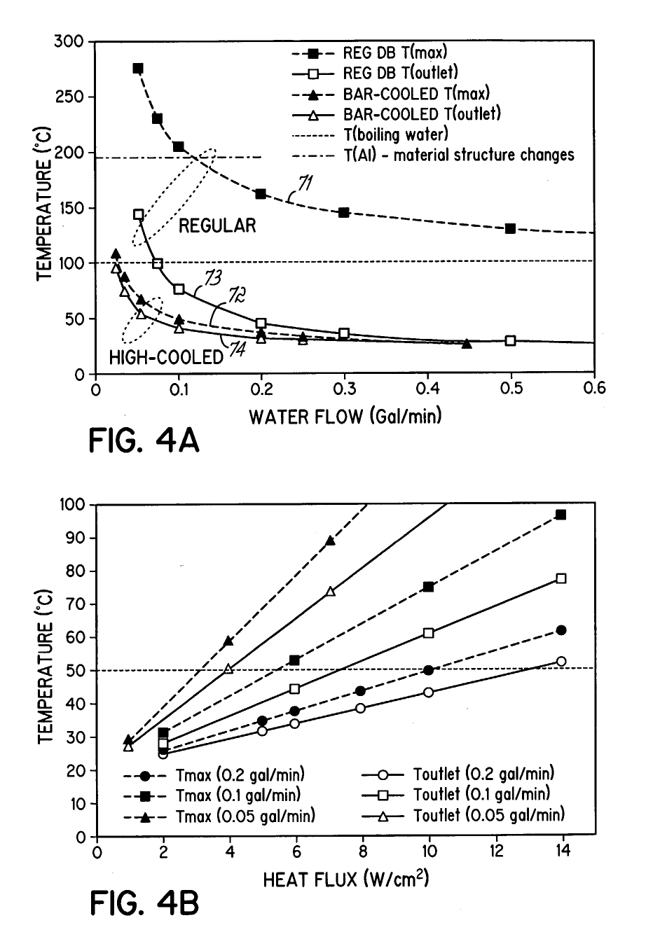

A comparison of the temperature extremes and temperature distribution that occurs during iPVD operation between the baffles 30 and 50 demonstrates advantages of the present invention. The maximum temperature on the baffles 30 and 50, which is found to occur at the center of the baffles 30 and 50, at the midpoint of the centermost one of the ribs 32 and 52, is depicted as curves 71 and 72, respectively, in the graph of FIG. 4A, as a function of cooling water flow. For the baffle 30, this temperature is above 120° C., while for the baffle 50, this temperature is as low as 30° C., for a given iPVD power. The cooling water temperature at the outlets 42 and 62, respectively, of the baffles 30 and 50, is depicted in curves 73 and 74 in the graph of FIG. 4A. FIG. 4B illustrates the maximum temperature and outlet water temperature of the baffle 50 for various cooling water flow rates and under a given set of iPVD operating conditions.

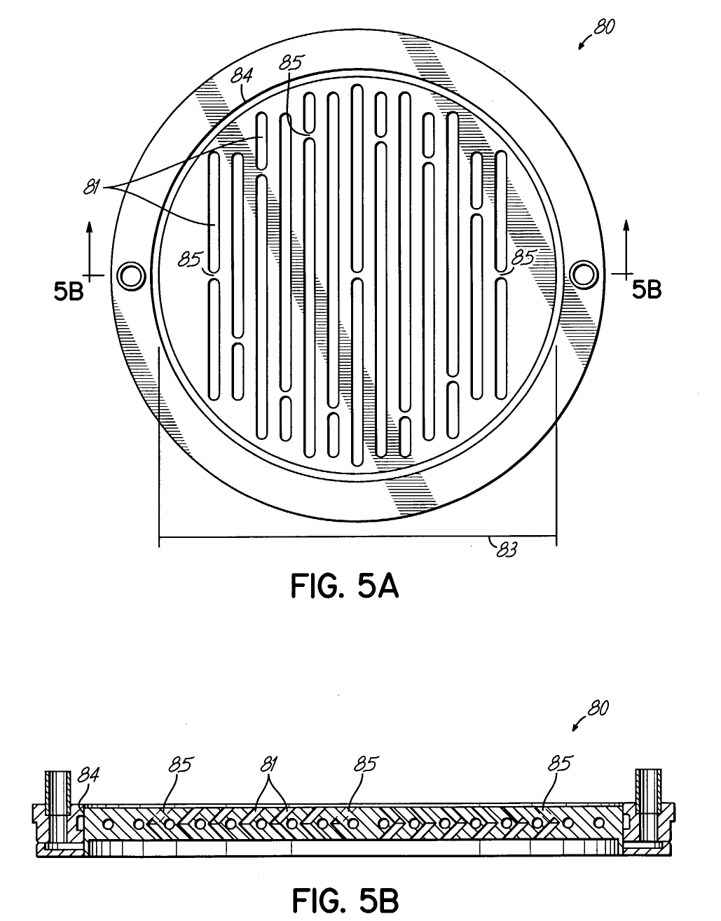

The uniformity of temperature across the baffle 50 reduces thermal stresses that can increase the flaking of deposits from the baffle 50 that would cause particulate contaminates in the iPVD process chamber 11. Where bridges across the slots 51 of the baffle 50 are desirable, for reasons explained in U.S. patent application Ser. No. 10/080,496, referred to above, locating the bridges on the window side of the baffle 50 has been found to further result in less flaking and particulate contamination. Such a baffle is illustrated in FIGS. 5A and 5B.

Referring to FIGS. 5A and 5B, a baffle 80 is illustrated that is similar in all respects to the baffle 50 described above except that bridges 85 have been added across slots 81, which are parallel slots arranged perpendicular to a diameter 83, as illustrated. Each of the slots 81 extends along a cord across the circular inner part of the baffle body to near its perimeter 84, as shown in FIG. 5A. Each slot 81 is interrupted at at least one point by one of the bridges 85. These bridges are located across the slots on only the window side of the baffle 80, as illustrated in FIG. 5A. The location of the bridges 85 on the window side of the baffle 80 further reduces the likelihood of particle contamination, which is believed to be because it enhances the temperature uniformity on the plasma side of the baffle.

Deposition baffles having features of the present invention are particularly useful in deposition modules of the types described in U.S. Pat. Nos. 6,287,435; 6,197,165 and 6,080,287, and U.S. patent application Ser. Nos. 09/629,515; 09/796,971 and 10/080,496. However, the baffles of the present invention are also useful with other ICP reactors.

Those skilled in the art will appreciate that the application of the present invention herein is varied, that the invention is described in exemplary embodiments, and that additions and modifications can be made without departing from the principles of the invention. Therefore, the following is claimed:

1. A deposition baffle for protecting a dielectric window in a wall of a plasma processing chamber while facilitating inductive coupling of RF energy from a coil outside of the window, through the window and baffle, and into a plasma in a plasma processing space within the chamber, comprising:
an electrically conductive body having a window side and a plasma side;
the body having a plurality of slots extending therethrough between the sides thereof;
the body having a rib portion between each adjacent pair of the slots;
the slots having walls defined by surfaces of the body and being configured to block line-of-sight paths through the body for particles in the chamber to move from the plasma side of the body to the window side of the body;
a plurality of the slots each having a structural element therein fixed to the body on substantially only the window side of the body; and
the elements having connections to the body distributed on the baffle so as to improve the uniformity of the distribution of power coupled into the plasma through the baffle without limiting the effectiveness of inductive coupling through the baffle.

2. The baffle of claim 1 wherein:
the slots have chevron-shaped cross sections when viewed along the length of the slots.

3. The baffle of claim 1 wherein:
the elements are electrically conductive bridges electrically interconnecting opposite walls of the slots thereby interrupting the slots on the window side of the body.

4. The baffle of claim 1 wherein:
the body has formed therein a cooling fluid inlet, a cooling fluid outlet and at least one cooling fluid channel forming a cooling fluid path from the inlet to the outlet, the channel extending within the body along at least one rib portion thereof.

5. The baffle of claim 1 wherein:
the body has formed therein a cooling fluid inlet, a cooling fluid outlet and at least one cooling fluid channel forming a cooling fluid path from the inlet to the outlet, the channel extending within the body along each of rib portions thereof.

6. The baffle of claim 1 wherein:
the body has formed therein a cooling fluid inlet, a cooling fluid outlet and at least one cooling fluid channel forming a cooling fluid path from the inlet to the outlet, the channel extending within the body sequentially along a plurality of rib portions thereof.

7. The baffle of claim 6 wherein:
the slots include a plurality of generally parallel slots extending perpendicular to a diameter through the center of the body; and
the elements are electrically conductive bridges electrically interconnecting opposite walls of each of the slots interrupting the slots such that none of the slots is a single continuous slot extending across the baffle on both sides of said diameter.

8. The baffle of claim 7 wherein:
at least a portion of the channel extends along each of the rib portions between each adjacent pair of the slots, each of said portions of the channel forming a continuous sequential cooling fluid path from the inlet to the outlet.

9. An plasma source for inductively coupling RF energy into a plasma processing space within a plasma processing chamber, comprising:
a dielectric window in a wall of the plasma processing chamber;
an RF antenna outside of the window connected to an RF power source;
the deposition baffle of claim 1 proximate the window inside of the chamber between the window and the processing space, with the window side thereof facing the dielectric window and the plasma side thereof facing the plasma processing space.

10. The method of providing low particle contamination while protecting a window from deposits in an iPVD process comprising the step of providing the baffle of claim 1 to maintain relatively uniform temperature gradients adjacent a dielectric window on the inside of a deposition chamber.

11. A deposition baffle for protecting a dielectric window in the wall of a plasma processing chamber while facilitating inductive coupling of RF energy from a coil outside of the window, through the window and baffle, and into a plasma within the chamber, comprising:
an electrically conductive body having a plurality of slots extending therethrough so as to interrupt current paths in the body so that, when the baffle is situated in a predetermined position and orientation in relation to the coil, RF energy couples through the baffle, the body having at least one surface thereof conditioned to facilitate the adhesion thereto of deposition material from the plasma processing chamber;
the slots being configured so that, when so situated, line-of-sight paths for particles in the chamber moving toward the window are blocked;
the body including rib portions, one defined between each pair of adjacent slots; and
the body having a cooling fluid inlet, a cooling fluid outlet and at least one cooling fluid channel forming a cooling fluid path from the inlet to the outlet, the at least one channel extending within the body along a plurality of the rib portions, the channel being configured to facilitate cooling fluid flow through the body so as to maintain sufficiently uniform temperature distribution to prevent substantial flaking of deposited material from the conditioned surface of the body.

12. The baffle of claim 11 wherein:
the body is generally flat with the rib portions lying parallel to a plane.

13. The baffle of claim 11 wherein:
the slots include a plurality of generally parallel slots; and
the body includes a plurality of electrically conductive bridges each interrupting a slot so that no slot extends substantially across the diameter of the body.

14. The baffle of claim 11 wherein:
the channel has a plurality of intermediate sections connected in series between the inlet and the outlet;
each of the rib portions has one of the intermediate sections of the channel extending the length thereof; and
the channel forms a continuous cooling fluid path from the inlet sequentially along each of the intermediate sections of the channel and to the outlet.

15. The baffle of claim 11 wherein:
the channel has a plurality of intermediate sections between the inlet and the outlet;
each of the rib portions has one of the intermediate sections of the channel extending the length thereof; and
the intermediate sections are connected in series between the inlet and the outlet such that a flow path is formed therethrough that alternates in direction from intermediate section to intermediate section from the inlet to the outlet;
whereby the channel forms a single continuous serpentine cooling fluid path from the inlet sequentially along each of the intermediate sections of the channel and to the outlet.

16. The baffle of claim 11 wherein:
the channel has a plurality of intermediate sections between the inlet and the outlet;
each of the rib portions has one of the intermediate sections of the channel extending the length thereof; and
the channel forms a cooling fluid path from the inlet through each of the intermediate sections of the channel and to the outlet.

17. The baffle of claim 16 wherein:
the slots include a plurality of generally straight slots parallel to each other and extending perpendicular to a diameter through the center of the body; and
the body includes a plurality of electrically conductive bridges electrically interconnecting opposite walls of a plurality of the slots and interrupting the slots such that none of the slots is a single continuous slot extending across the shield on both sides of said diameter.

18. The baffle of claim 17 wherein the body includes:
a central circular part and an annular outer part;
the central circular part being bounded by a periphery, having the slots, the ribs and the intermediate sections of the channel bored therein from the periphery and extending along the entire length of a respective one of the ribs; and
the annular part surrounding the circular part, having an internal side bonded to the periphery of the circular part, having the inlet and outlet therein, and having interconnecting channel portions formed in the internal side thereof serially interconnecting different ones of the intermediate sections of the channel to form the continuous cooling fluid path from the inlet, through the channel and to the outlet.

19. The baffle of claim 11 wherein:
the channel has a plurality of intermediate sections between the inlet and the outlet;
the body includes a central circular part having a periphery and having the slots, the ribs and the intermediate sections of the channel therein;
each of the intermediate sections of the channel extending along one of the ribs and having opposite ends lying on the periphery of the central circular part, every point along the intermediate sections being accessible along a straight length of the section from at least one of said ends; and
the body also includes an annular part surrounding the central circular part and having an internal side thereof adjacent and bonded to the periphery thereof of the central circular part;
the channel having interconnecting portions thereof formed in the internal side of the annular part and connecting each of the intermediate sections of the channel between the inlet and outlet ports.

20. An inductively-coupled-plasma source for inductively coupling RF energy into a plasma processing space within a plasma processing chamber, comprising:
a dielectric window in a wall of the plasma processing chamber;
a coil outside of the window and connected to an RF power source; and
the deposition baffle of claim 11 in the chamber between the window and the processing space.

21. The method of providing low particle contamination while protecting a window from deposits in a plasma process comprising the step of providing the baffle of claim 11 to maintain relatively uniform temperature gradients adjacent a dielectric window on the inside of a deposition chamber.

22. A deposition baffle for protecting a dielectric window in the wall of a plasma processing chamber while facilitating inductive coupling of RF energy from a coil outside of the window, through the window and baffle, and into a plasma within the chamber, comprising:
an electrically conductive body having a plurality of slots extending therethrough so as to interrupt current paths in the body so that, when the baffle is situated in a predetermined position and orientation in relation to the coil, RF energy couples through the baffle;
the body including rib portions, one defined between each pair of adjacent slots;
the body having a cooling fluid inlet, a cooling fluid outlet and at least one cooling fluid channel forming a cooling fluid path from the inlet to the outlet, the at least one channel extending within the body along a plurality of the rib portions;
the channel having a plurality of intermediate sections between the inlet and the outlet;
the body including a central circular part having a periphery and having the slots, the ribs and the intermediate sections of the channel therein;
each of the intermediate sections of the channel extending along one of the ribs and having opposite ends lying on the periphery of the central circular part; and
the body also including an annular part surrounding the central circular part and having an internal side thereof adjacent and bonded to the periphery thereof of the central circular part; and
the channel having interconnecting portions thereof formed in the internal side of the annular part and connecting each of the intermediate sections of the channel between the inlet and outlet ports.

23. The baffle of claim 22 wherein:
every point along the intermediate sections being accessible along a straight length of the section from at least one of said ends.

24. The baffle of claim 22 wherein:
the slots include a plurality of generally parallel slots; and
the body includes a plurality of electrically conductive bridges each interrupting a slot so that no slot extends substantially across the diameter of the central circular part of the body.

25. The baffle of claim 22 wherein:
the intermediate sections are connected in series between the inlet and the outlet such that a continuous serpentine cooling fluid flow path is formed therethrough that alternates in direction from intermediate section to intermediate section from the inlet to the outlet.

26. A plasma processing method comprising:
coupling RF energy through a dielectric window in the wall of a plasma processing chamber from a coil outside of the window, through the window and into a plasma within the chamber;
protecting the window with a baffle proximate the window on the inside of the chamber having an electrically conductive body with a plurality of slots extending therethrough that interrupt current paths in the body, the baffle being positioned and oriented in relation to the coil such that the RF energy couples through the baffle, the slots being configured to block line-of-sight paths for particles in the chamber moving toward the window; and
cooling the baffle by flowing a cooling fluid through a cooling fluid channel extending within the baffle between adjacent pairs of slots to facilitate cooling fluid flow through the body and maintain sufficiently uniform temperature distribution to prevent substantial flaking of deposited material from the conditioned surface of the body.

27. The method of claim 26 wherein:
the cooling includes flowing the cooling liquid through a continuous cooling fluid channel extending from an inlet in the baffle, sequentially between each of a plurality of adjacent pairs of slots and to an outlet in the baffle.
